(19) United States
(12) Patent Application Publication
(10) Pub. No.: US 2016/0247909 A1
(43) Pub. Date: Aug. 25, 2016

(54) SEMICONDUCTOR DEVICE AND METHOD OF MANUFACTURING THE SAME

(71) Applicant: KABUSHIKI KAISHA TOSHIBA, Minato-ku (JP)

(72) Inventor: Koichi MATSUNO, Mie (JP)

(73) Assignee: KABUSHIKI KAISHA TOSHIBA, Minato-ku (JP)

(21) Appl. No.: 14/847,501

(22) Filed: Sep. 8, 2015

Related U.S. Application Data
(60) Provisional application No. 62/117,987, filed on Feb. 19, 2015.

(51) Int. Cl. H01L 29/788; H01L 23/535; H01L 29/51; H01L 21/28; H01L 29/66; H01L 29/49

(52) U.S. Cl. CPC H01L 29/788; H01L 29/66825; H01L 29/4925; H01L 29/518; H01L 21/28273; H01L 23/535

(57) ABSTRACT

In one embodiment, a semiconductor device includes a substrate, and a gate conductor provided on the substrate. The device further includes a first insulator provided on the gate conductor, a second insulator provided on the first insulator and including an opening, and a third insulator provided on the second insulator and provided in the opening. The device further includes a first contact plug provided in the first and third insulators, positioned in the opening, and electrically connected to the gate conductor.

### CROSS REFERENCE TO RELATED APPLICATION

This application is based upon and claims the benefit of priority from the prior U.S. Provisional Patent Application No. 62/117,987 filed on Feb. 19, 2015, the entire contents of which are incorporated herein by reference.

### FIELD

Embodiments described herein relate to a semiconductor device and a method of manufacturing the same.

### BACKGROUND

A semiconductor device such as a NAND flash memory includes various lines such as word lines, bit lines, contact plugs (contact lines) and via plugs (via lines). Forming these lines involves the following problems.

For example, the NAND flash memory includes various contact plugs such as bit line contacts and gate contacts in a memory cell region, and gate contacts and diffusion layer contacts in a peripheral transistor region. From the viewpoint of an etching process, it is however difficult to simultaneously form these contact plugs. The reason is that the number of layers etched to form contact holes for the contact plugs differs depending on the contact plugs. Therefore, it is desired to employ a method that allows the contact holes to be easily formed simultaneously.

Furthermore, a line of the NAND flash memory often includes a metallic layer such as a tungsten (W) layer. For example, in a case where the line including the metallic layer is formed on an air gap between the word lines, if the metallic layer is in contact with the air gap, a chemical for etching the metallic layer may intrude into the air gap. In this case, if the word lines also include metallic layers, the chemical may dissolve the metallic layers, the dissolved metal may be deposited, and the deposited metal may cause a short circuit between the word lines. In addition, when the word lines include the metallic layers, the metallic layers are exposed after the word lines are processed. In this case, if the metallic layers are left exposed, contamination by the metallic layers may have an adverse effect on the reliability of memory cells. It is known that these problems appear when the metallic layers are tungsten layers, for example.

### BRIEF DESCRIPTION OF THE DRAWINGS

FIGS. 1A to 7C are cross sectional views and plan views showing a method of manufacturing a semiconductor device of a first embodiment;

FIGS. 8A to 8C are cross sectional views for illustrating advantages of the method of manufacturing the semiconductor device of the first embodiment;

FIGS. 9A to 9E are plan views and cross sectional views showing a method of manufacturing a semiconductor device of a modification of the first embodiment; and

FIGS. 10A to 14B are cross sectional views showing a method of manufacturing a semiconductor device of a second embodiment.

### DETAILED DESCRIPTION

Embodiments will now be explained with reference to the accompanying drawings.

In one embodiment, a semiconductor device includes a substrate, and a gate conductor provided on the substrate. The device further includes a first insulator provided on the gate conductor, a second insulator provided on the first insulator and including an opening, and a third insulator provided on the second insulator and provided in the opening. The device further includes a first contact plug provided in the first and third insulators, positioned in the opening, and electrically connected to the gate conductor.

### First Embodiment

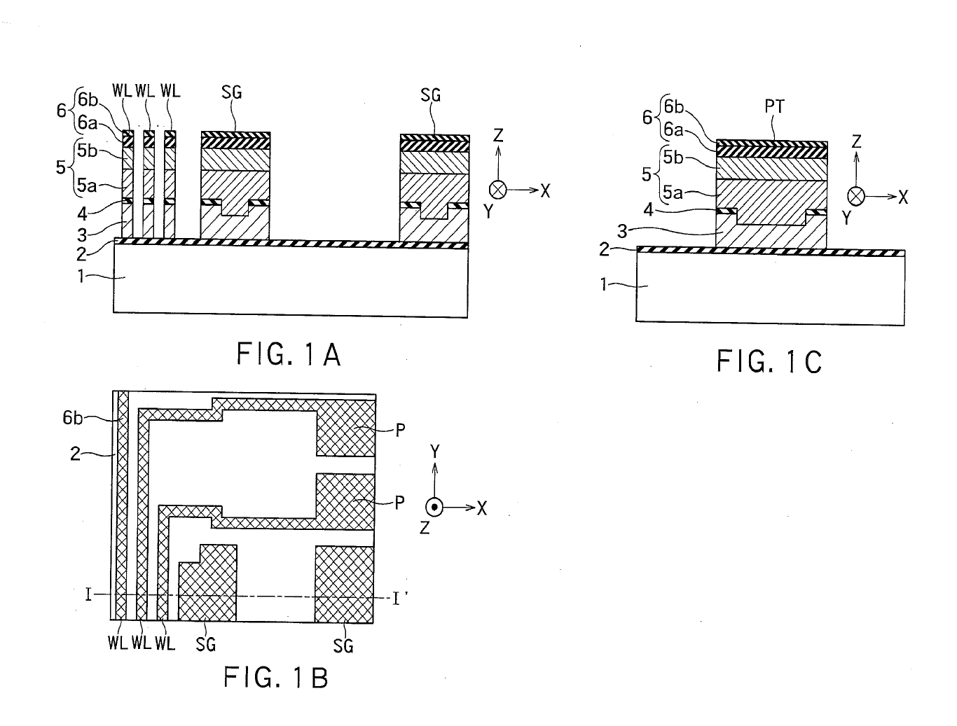

FIGS. 1A to 7C are cross sectional views and plan views showing a method of manufacturing a semiconductor device of a first embodiment.

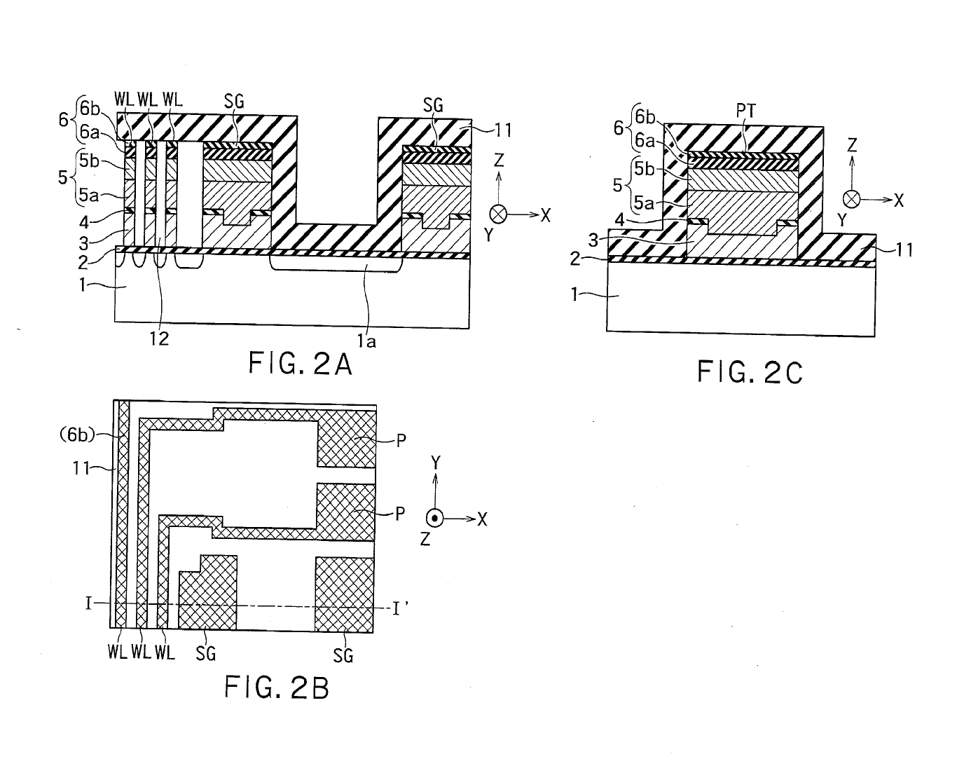

The semiconductor device in the present embodiment is a NAND flash memory. FIGS. 1A and 1B are a cross sectional view and a plan view showing a memory cell region of the semiconductor device in the present embodiment. FIG. 1A shows a cross section taken along a line I-I′ in FIG. 1B. FIG. 1C is a cross sectional view showing a peripheral transistor region of the semiconductor device in the present embodiment. This is also applied to FIGS. 2A to 7C.

[FIGS. 1A to 1C]

First, word lines WL including cell transistors, select gates SG including select transistors, and a peripheral transistor PT are formed on a substrate 1 (FIGS. 1A to 1C). Cross hatchings in FIG. 1B show regions where the word lines WL and the select gates SG are formed.

Each cell transistor includes the substrate 1, a gate insulator 2, a first conductive layer 3 that functions as a floating gate, an inter gate insulator 4, a second conductive layer 5 that functions as a control gate (word line WL), and a mask layer 6. The first conductive layer 3 is an example of a charge storage layer. The second conductive layer 5 is an example of a gate conductor.

An example of the substrate 1 is a semiconductor substrate such as a silicon substrate. FIGS. 1A to 1C show an X direction and a Y direction that are parallel to the surface of the substrate 1 and orthogonal to each other, and a Z direction that is orthogonal to the surface of the substrate 1. The X direction and the Y direction are examples of a first direction and a second direction, respectively. In the present specification, a +Z direction is treated as an upward direction, and a −Z direction is treated as a downward direction. For example, the positional relationship between the substrate 1 and the first conductive layer 3 is expressed that the substrate 1 is positioned below the first conductive layer 3. The −Z direction in the present embodiment may be identical to the gravity direction, or may not be identical to the gravity direction.

The gate insulator 2 is formed on the substrate 1. An example of the gate insulator 2 is a silicon oxide film.

The first conductive layer 3 is formed on the gate insulator 2. An example of the first conductive layer 3 is a polysilicon layer. The first conductive layer 3 of each cell transistor is used for storing signal charges.

The inter gate insulator 4 is formed on the first conductive layer 3. An example of the inter gate insulator 4 is a silicon oxide film.

The second conductive layer 5 is formed on the inter gate insulator 4. The second conductive layer 5 in the present embodiment includes a semiconductor layer 5a on the inter gate insulator 4 and a metallic layer 5b on the semiconductor layer 5a. An example of the semiconductor layer 5a is a polysilicon layer. An example of the metallic layer 5b is a tungsten layer.

The mask layer 6 is formed on the second conductive layer 5. The mask layer 6 in the present embodiment includes a first mask layer 6a on the second conductive layer 5 and a second mask layer 6b on the first mask layer 6a. An example of the first mask layer 6a is a silicon nitride film. An example of the second mask layer 6b is a silicon oxide film. The mask layer 6 is used as a hard mask in processing the cell transistors, the select transistors and the peripheral transistor PT.

Each select transistor includes, similarly to each cell transistor, the substrate 1, the gate insulator 2, the first conductive layer 3 that functions as a portion of a gate electrode (select gate SG), the inter gate insulator 4, the second conductive layer 5 that functions as a portion of the gate electrode (select gate SG), and the mask layer 6. The first conductive layer 3 and the second conductive layer 5 of each select transistor are electrically connected to each other through the opening of the inter gate insulator 4.

The peripheral transistor PT includes, similarly to each cell transistor and each select transistor, the substrate 1, the gate insulator 2, the first conductive layer 3 that functions as a portion of a gate electrode, the inter gate insulator 4, the second conductive layer 5 that functions as a portion of the gate electrode, and the mask layer 6. The first conductive layer 3 and the second conductive layer 5 of the peripheral transistor PT are electrically connected to each other through the opening of the inter gate insulator 4.

The cell transistors, the select transistors and the peripheral transistor PT are sequentially formed by forming the gate insulator 2, the first conductive layer 3, the inter gate insulator 4, the second conductive layer 5 and the mask layer 6 on the substrate 1 and performing gate processing on these layers. At this point, pad electrodes P electrically connected to the word lines WL are also formed. The pad electrodes P are formed of the second conductive layer 5.

[FIGS. 2A to 2C]

Next, an insulator 11 is formed on the whole surface of the substrate 1 by plasma chemical vapor deposition (CVD) (FIGS. 2A to 2C). The insulator 11 is, for example, a silicon oxide film. The mask layer 6 and the insulator 11 are examples of a first insulator. The first mask layer 6a (silicon nitride film) is an example of a first layer of the first insulator. The second mask layer 6b (silicon oxide film) and the insulator 11 (silicon oxide film) are examples of a second layer of the first insulator.

In the present embodiment, air gaps 12 are formed between the cell transistors (word lines WL) under the insulator 11. For example, these air gaps 12 can be formed by using, as the insulator 11, an insulator having poor embedding properties. The insulator 11 in the present embodiment is formed on the mask layer 6 of the cell transistors, the select transistors and the peripheral transistor PT, and on the side faces of the select transistors and the peripheral transistor PT. Also, the insulator 11 in the present embodiment is thinly formed on the side faces of the cell transistors and the upper faces of the gate insulator 2 between the cell transistors.

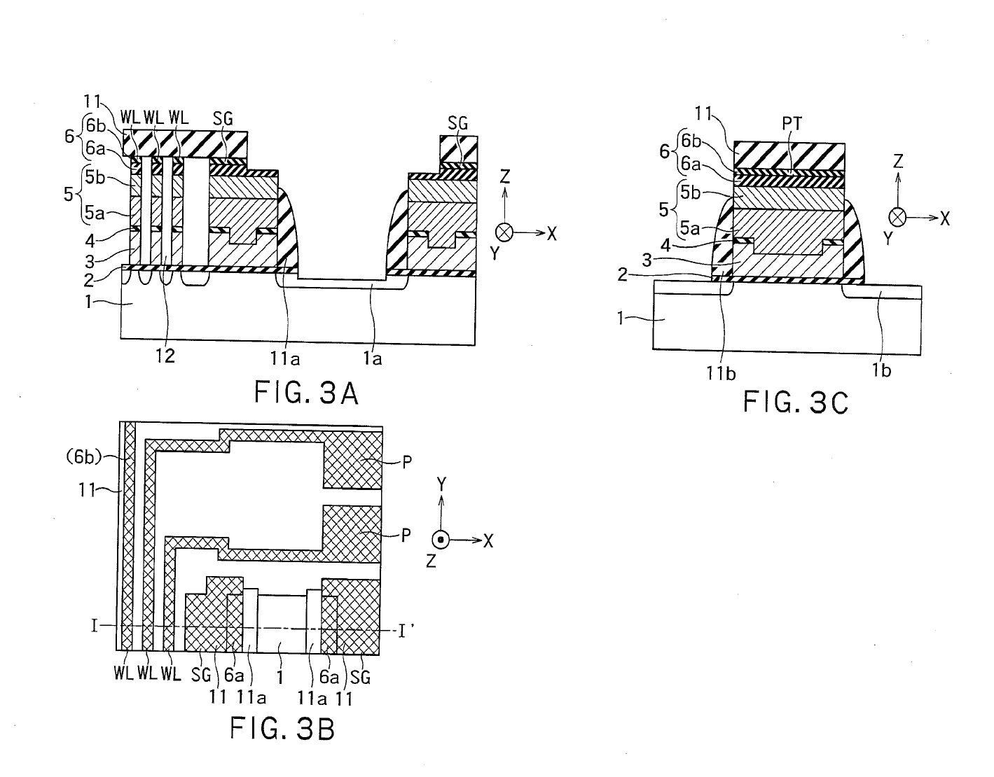

Next, diffusion layers 1a are formed in the substrate 1 by ion implantation (FIGS. 2A to 2C). In the memory cell region, the diffusion layers 1a are formed between the cell transistors, between the cell and select transistors, and between the select transistors.

[FIGS. 3A to 3C]

Next, a resist mask (not shown) is formed above the air gaps 12 by lithography. This resist mask is formed for preventing the insulator 11 from being etched to open the air gaps 12.

Next, the insulator 11 is processed by reactive ion etching (RIE) with the resist mask to form spacers 11a and 11b from the insulator 11 (FIGS. 3A to 3C). The spacers 11a are formed on the side faces of the select transistors. The spacers 11b are formed on the side faces of the peripheral transistor PT.

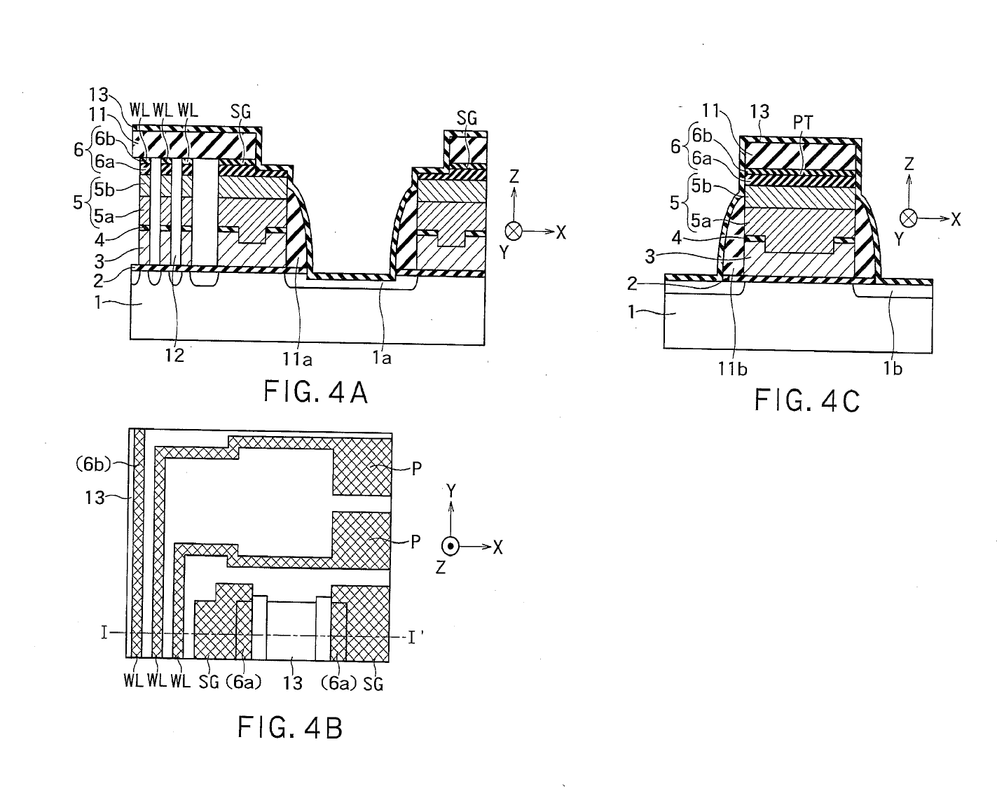

Next, diffusion layers 1b are formed in the substrate 1 by ion implantation (FIGS. 3A to 3C). The diffusion layers 1b are formed to sandwich the peripheral transistor PT in the peripheral transistor region. The diffusion layers 1b function as a source diffusion layer and a drain diffusion layer of the peripheral transistor PT.

[FIGS. 4A to 4C]

Next, an insulator 13 is formed on the whole surface of the substrate 1 by low pressure (LP) CVD (FIGS. 4A to 4C). As a result, the insulator 13 is formed on the insulator 11 on the cell transistors, the select transistors and the peripheral transistor PT, on the diffusion layer 1a between the select transistors, and on the diffusion layers 1b for the peripheral transistor PT. The insulator 13 in the present embodiment is used as an etching stopper in a contact process. The insulator 13 is, for example, a silicon nitride film. The insulator 13 is an example of a second insulator. The insulator 13 is an example of a second insulator that is formed of a same kind of insulator material as the first layer of the first insulator.

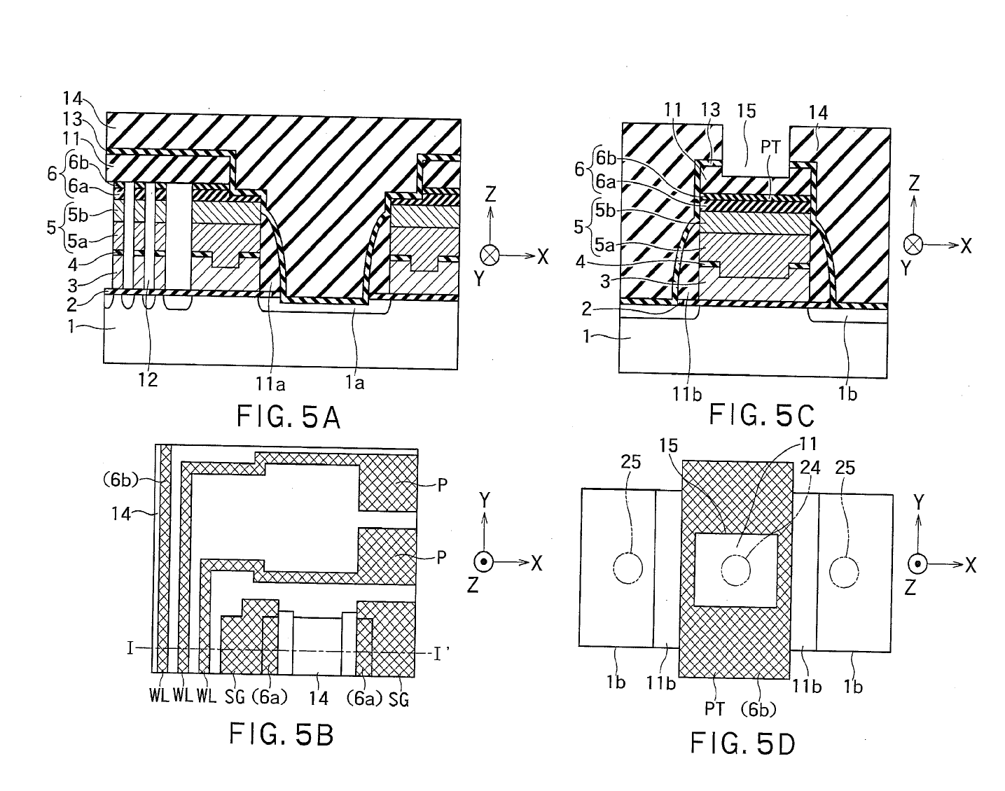

In the processes of FIGS. 4A to 4C, the silicon oxide film may be formed on the whole surface of the substrate 1 by LPCVD before the insulator 13 is formed. The thickness of the silicon oxide film is, for example, about 10 nm. This silicon oxide film is also an example of the second layer of the first insulator.

[FIGS. 5A to 5D]

Next, a resist film 14 is formed on the whole surface of the substrate 1 (FIGS. 5A to 5D). Next, an opening is formed in the resist film 14 above the peripheral transistor PT by lithography. Next, an opening 15 is formed in the insulator 13 above the peripheral transistor PT by RIE with the resist film 14. In addition, the thickness of the insulator 11 above the peripheral transistor PT is reduced by this RIE. The resist film 14 is removed thereafter.

FIG. 5D is a plan view showing the peripheral transistor region of the semiconductor device in the present embodiment. FIG. 5D shows, similarly to FIG. 5C, the opening 15 formed in the insulator 13. FIG. 5D further shows a region where a gate contact 24 is to be formed and regions where diffusion layer contacts 25 are to be formed. As shown in FIG. 5D, the gate contact 24 in the present embodiment is formed in the opening 15.

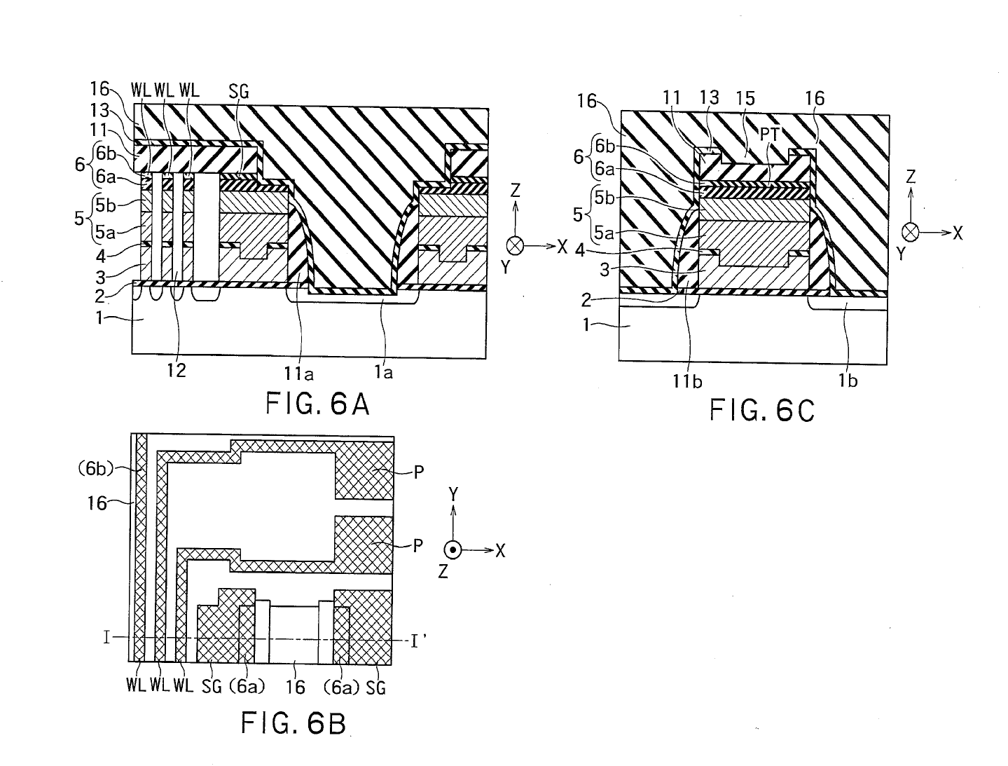

In the present embodiment, openings (not shown) are also formed in the resist film 14 above the pad electrodes P and the select gates SG by the above-described lithography. Furthermore, openings (not shown) are also formed in the insulator 13 above the pad electrodes P and the select gates SG by the above-described RIE. Gate contacts 22 and 23 for the pad electrodes P and the select gates SG (to be described hereafter) are formed in the openings in the insulator 13, similarly to the gate contacts 24.

[FIGS. 6A to 6C]

Next, an inter layer dielectric 16 is formed on the whole surface of the substrate 1 by plasma CVD (FIGS. 6A to 6C). The inter layer dielectric 16 is, for example, a silicon oxide film. The inter layer dielectric 16 is an example of a third insulator. The inter layer dielectric 16 is an example of the third insulator that is formed of a same kind of insulator material as the second layer of the first insulator. The surface of the inter layer dielectric 16 is then planarized by chemical mechanical polishing (CMP).

The inter layer dielectric 16 in the present embodiment is formed not only on the insulator 13 but also in the opening 15 in the insulator 13. Therefore, the inter layer dielectric 16 in the present embodiment is formed on the insulator 11 through the insulator 13 and formed directly on the insulator 11 on the peripheral transistor PT. The inter layer dielectric 16 is also formed above the diffusion layers is between the select transistors and above the diffusion layers 1b for the peripheral transistor PT through the insulator 13.

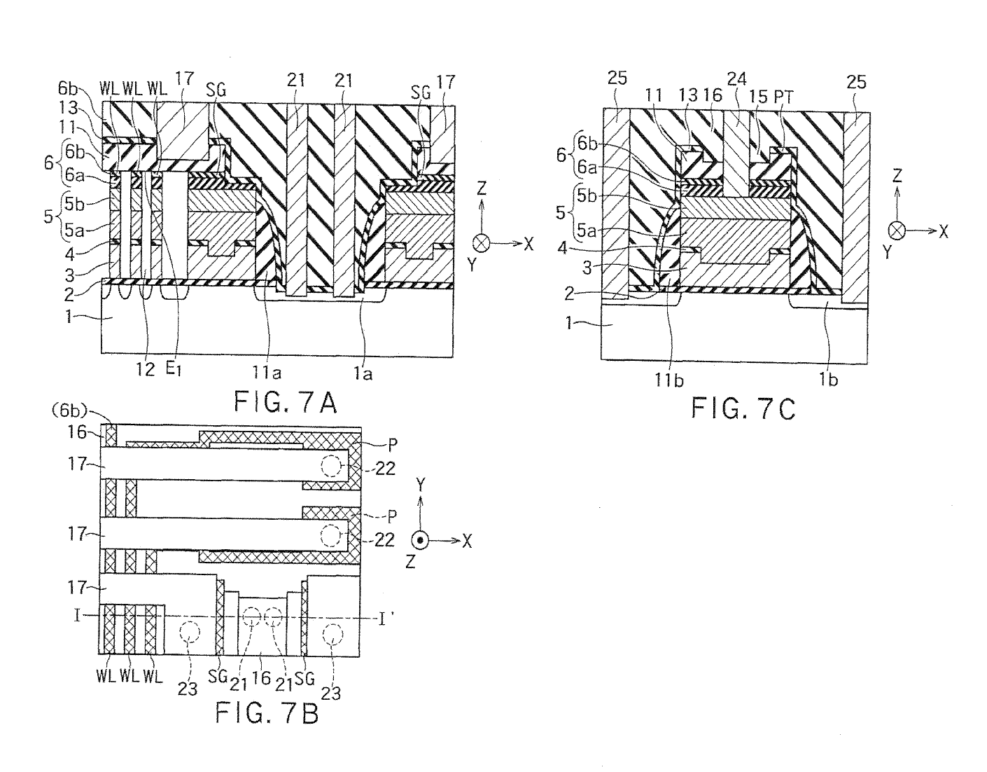

In addition, the inter layer dielectric 16 in the present embodiment is formed in the openings in the insulator 13 on the pad electrodes P and the select gates SG. Therefore, the inter layer dielectric 16 in the present embodiment is also formed directly on the insulator 11 on the pad electrodes P and the select gates SG.

[FIGS. 7A to 7C]

Next, lines such as metal lines 17, bit line contacts 21, the gate contacts 22, 23 and 24 and the diffusion layer contacts 25 are formed by lithography, RIE and metal CVD (FIGS. 7A to 7C). These lines are, for example, metallic layers such as tungsten layers. The gate contacts 22, 23 and 24 are examples of a first contact plug. The bit line contacts 21 and the diffusion layer contacts 25 are examples of a second contact plug. The metal lines 17 are an example of a metallic layer above an air gap.

These lines are formed in the following manner. First, a resist film (not shown) is formed on the whole surface of the substrate 1. Next, openings used for forming these lines are formed in the resist film by lithography. Next, openings (contact holes) used for forming these lines are simultaneously formed in the inter layer dielectric 16 and the like by RIE using the resist film. The resist film is then removed and thereafter a line material is simultaneously embedded in the openings formed in the inter layer dielectric 16 and the like. An example of the line material is a metal such as tungsten. Unnecessary line material outside the openings is then removed by etching. In this way, the lines such as the metal lines 17, the bit line contacts 21, the gate contacts 22, 23 and 24 and the diffusion layer contacts 25 are formed simultaneously.

The bit line contacts 21 are formed in the contact holes that penetrate the inter layer dielectric 16 and the insulator 13 in the memory cell region and electrically connected to the substrate 1. Specifically, the bit line contacts 21 are formed on the diffusion layer 1a between the select transistors. The contact holes for the bit line contacts 21 are formed by an etching process of penetrating a silicon oxide film (the inter layer dielectric 16) and an etching process of penetrating a silicon nitride film (the insulator 13).

The diffusion layer contacts 25 are formed in the contact holes that penetrate the inter layer dielectric 16 and the insulator 13 in the peripheral transistor region and electrically connected to the substrate 1. Specifically, the diffusion layer contacts 25 are formed on the diffusion layers 1b for the peripheral transistor PT. The contact holes for the diffusion layer contacts 25 are formed by an etching process of penetrating a silicon oxide film (the inter layer dielectric 16) and an etching process of penetrating a silicon nitride film (the insulator 13).

The gate contact 24 is formed in the contact hole that penetrates the inter layer dielectric 16, the insulator 11, the second mask layer 6b and the first mask layer 6a on the peripheral transistor PT and electrically connected to the second conductive layer 5 of the peripheral transistor PT. The gate contact 24 in the present embodiment is formed in the opening 15 of the insulator 13. Therefore, the contact hole for the gate contact 24 is formed without an etching process of penetrating the insulator 13. Specifically, the contact hole for the gate contact 24 is formed by an etching process of penetrating a silicon oxide film (the inter layer dielectric 16, the insulator 11 and the second mask layer 6b), and an etching process of penetrating a silicon nitride film (the first mask layer 6a).

Similarly, the gate contacts 22 and 23 are formed in the contact holes that penetrate the inter layer dielectric 16, the insulator 11, the second mask layers 6b, and the first mask layers 6a on the pad electrodes P and the select gates SG and electrically connected to the second conductive layers 5 (the pad electrodes P or the select gates SG). The gate contacts 22 and 23 in the present embodiment are formed in the openings of the insulator 13 on the pad electrodes P and the select gates SG. Therefore, the contact holes for the gate contacts 22 and 23 are formed without an etching process of penetrating the insulator 13. Specifically, the contact holes for the gate contacts 22 and 23 are formed by an etching process of penetrating a silicon oxide film (the inter layer dielectric 16, the insulator 11 and the second mask layer 6b) and an etching process of penetrating a silicon nitride film (the first mask layer 6a).

The metal lines 17 are formed in the inter layer dielectric 16, the insulator 13 and the insulator 11, and are formed so as to pass on the word lines WL, the select gates SG, the pad electrodes P, the air gaps 12 and the like, for example. The metal lines 17 in FIG. 7A are formed in the insulator 11 (on the insulator 11) above the air gaps 12. The metal lines 17 in FIG. 7B are electrically connected to the gate contacts 22 and 23. The openings for embedding the metal lines 17 are formed by an etching process of penetrating a silicon oxide film (the inter layer dielectric 16) and an etching process of penetrating a silicon nitride film (the insulator 13). In the latter etching process, the silicon oxide film (the insulator 11) is used as an etching stopper.

The metal lines 17 in the present embodiment may include a dummy line that is not used as a line (interconnect). For example, the dummy line is disposed in a region where the ratio of the metal lines 17 and the contact plugs 21 to 25 per unit area is small. It is thereby possible to restrict such a region from being excessively recessed in the etching processes of FIGS. 7A to 7C. In addition, it is possible, by the dummy line, to suppress signal noise when the semiconductor device in the present embodiment is used.

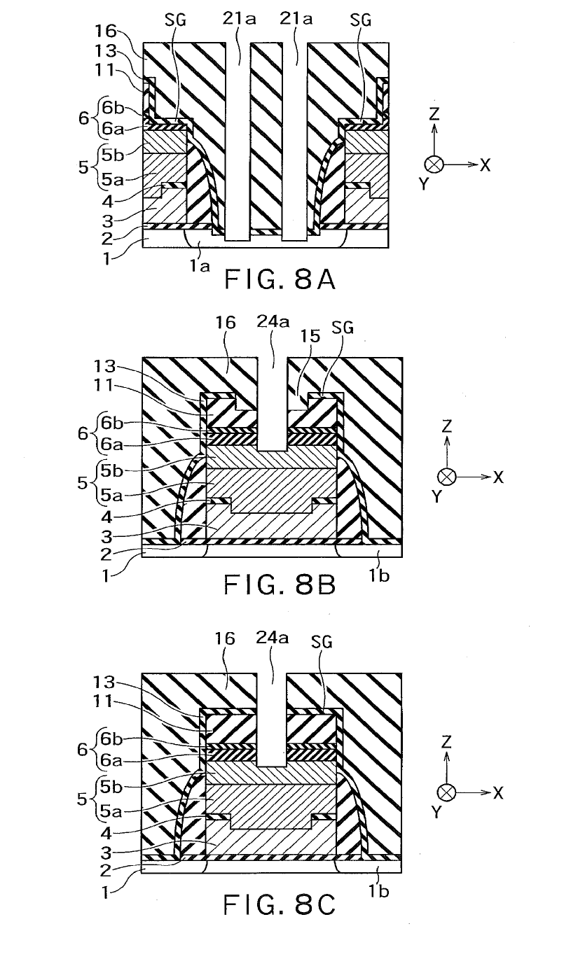

Various inter layer dielectrics, line layers, via plugs and the like are then formed on the substrate 1. In this way, the semiconductor device of the present embodiment is manufactured.

[FIGS. 8A to 8C]

FIGS. 8A to 8C are cross sectional views for illustrating advantages of the method of manufacturing the semiconductor device of the first embodiment.

FIGS. 8A and 8B are cross sectional views showing the memory cell region and the peripheral transistor region of the semiconductor device in the present embodiment. FIG. 8C is a cross sectional view showing a peripheral transistor region of a semiconductor device of a comparative example of the present embodiment.

FIG. 8A shows the contact holes 21a for the bit line contacts 21 in the present embodiment. The insulator penetrated by the contact hole 21a has a two-layered structure including the silicon oxide film (the inter layer dielectric 16) and the silicon nitride film (the insulator 13). Therefore, the contact holes 21a are formed by the etching process of penetrating the silicon oxide film and the etching process of penetrating the silicon nitride film. This is also applied to the contact holes for the diffusion layer contacts 25.

FIG. 8B shows the contact hole 24a for the gate contact 24 in the present embodiment. The insulator penetrated by the contact hole 24a also has a two-layered structure including the silicon oxide film (the inter layer dielectric 16, the insulator 11, and the second mask layer 6b) and the silicon nitride film (the first mask layer 6a). Therefore, the contact hole 24a is also formed by the etching process of penetrating the silicon oxide film and the etching process of penetrating the silicon nitride film. This is also applied to the contact holes for the gate contacts 22 and 23.

FIG. 8C shows a contact hole 24a for a gate contact 24 in the comparative example. The insulator penetrated by the contact hole 24a in the comparative example has a four-layered structure including an upper silicon oxide film (an inter layer dielectric 16), an upper silicon nitride film (an insulator 13), a lower silicon oxide film (an insulator 11 and a second mask layer 6b) and a lower silicon nitride film (a first mask layer 6a). Therefore, the contact hole 24a in the comparative example is formed by an etching process of penetrating the upper silicon oxide film, an etching process of penetrating the upper silicon nitride film, an etching process of penetrating the lower silicon oxide film and an etching process of penetrating the lower silicon nitride film. This is also applied to contact holes for gate contacts 22 and 23 in the comparative example.

The semiconductor device in the comparative example is formed by the gate contacts 22, 23 and 24 that are the type in FIG. 8C, and the bit line contacts 21 and the diffusion layer contacts 25 that are the type in FIG. 8A. In this case, it is required to form the contact holes penetrating the insulator having the two-layered structure, and the contact holes penetrating the insulator having the four-layered structure. It is therefore difficult to simultaneously form these contact plugs 21 to 25 from the viewpoint of an etching process. Accordingly, the etching processes for the contact holes may be complicated, leading to a deficiency such as unopened contact holes.

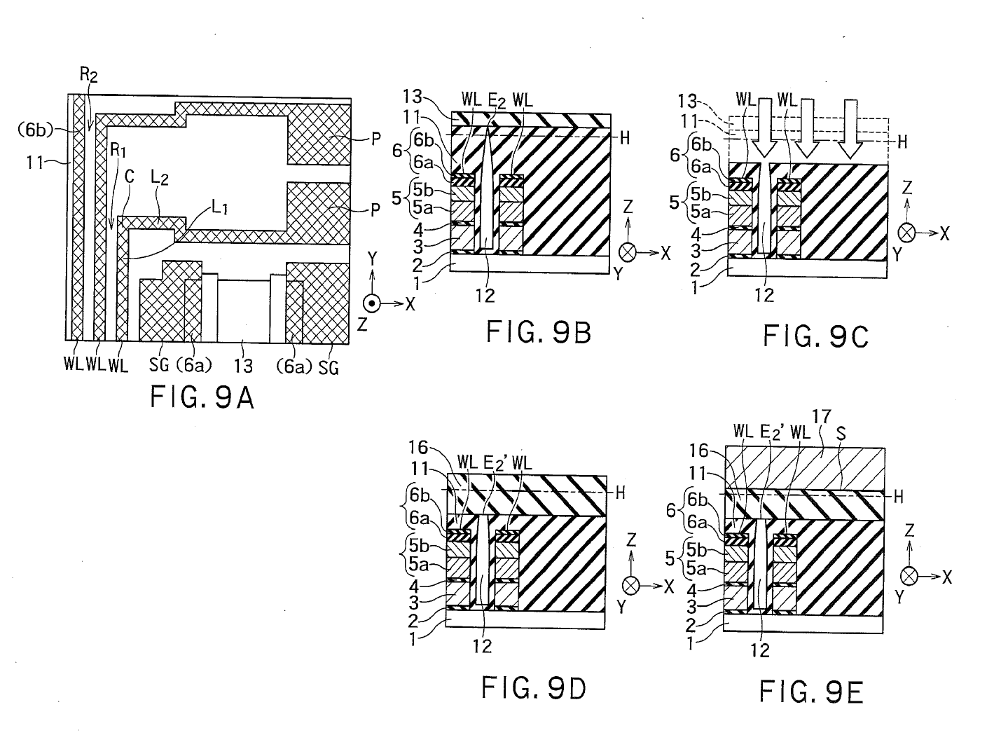

In contrast, the semiconductor device in the present embodiment is formed by the gate contacts 22, 23 and 24 that are the type in FIG. 8B, and the bit line contacts 21 and the diffusion layer contacts 25 that are the type in FIG. 8A. In this case, these contact plugs 21 to 25 are all formed using the contact holes penetrating the insulator having the two-layered structure. Therefore, according to the present embodiment, these contact plugs 21 to 25 are easily formed simultaneously. As a result, the present embodiment makes it possible to simplify the etching processes for the contact holes, enabling the improvement of a process margin for the unopening of the contact holes.

[FIGS. 9A to 9E]

FIGS. 9A to 9E are plan views and cross sectional views showing a method of manufacturing a semiconductor device of a modification of the first embodiment.

FIG. 9A is a plan view corresponding to FIGS. 4A to 4C. As shown in FIG. 9A, each word line WL includes a first portion L₁ extending in the Y direction, and a second portion. L₂ extending in the X direction. The Y direction is an example of a first direction. The X direction is an example of a second direction different from the first direction. Reference character C denotes a connection portion between the first portion L₁ and the second portion L₂ of each word line WL. The first portion L₁ includes cell transistors. The second portion L₂ extends from the connection portion C towards a pad electrode P for these cell transistors. Reference characters R₁ and R₂ denote regions near the connection portions C of the respective word lines WL.

FIG. 9B is a cross sectional view showing the region R₁ in FIG. 9A. FIG. 9B shows an air gap 12 that is formed between the word lines WL under the insulator 11. FIG. 9B also shows the insulator 11 that is thinly formed on the side portions and the lower portion of the air gap 12. This thinly formed insulator 11 is omitted to illustrate in FIGS. 2A to 7C.

The air gap 12 in FIG. 9B is positioned in proximity to the connection portion C between the first portion L₁ and the second portion L₂. The distance between the two word lines WL sandwiching the air gap 12 in FIG. 9B drastically increases in the vicinity of the connection portion C. The reason is that a direction in which one of the word lines WL extends changes at the connection portion C by 90 degrees from the Y direction to the X direction. For this reason, the upper end of the air gap 12 in the vicinity of the connection portion C tends to extend upward as compared with the air gap 12 in the other regions.

This is shown by first and second upper end E₁ and E₂ of the air gap 12 shown in FIGS. 7A and 9B. The first upper end E₁ in FIG. 7A is positioned between the cell transistor. The second upper end E₂ in FIG. 9B is positioned in the vicinity of the connection portion C. The first and second upper ends E₁ and E₂ are the upper ends of the same air gap 12. However, the second upper end E₂ is positioned higher than the first upper end E₁. Reference character H in FIG. 9B denotes the height of the first upper end E₁.

It is note that the upper face of the air gap 12 in FIG. 7A has a flat shape, and the upper face of the air gap 12 in FIG. 9B has a projecting shape. However, the upper face of the air gap 12 in FIG. 7A may also have a projecting shape.

In a case where a metal line 17 is formed above the second upper end E₂ of the air gap 12 in FIG. 9B, the metal line 17 may be in contact with the air gap 12. If the metal line 17 is in contact with the air gap 12, a chemical for etching the metal line 17 may intrude into the air gap 12. In this case, if the chemical intruding into the air gap 12 comes in contact with the metallic layer 5b of the word lines WL, the chemical may dissolve the metallic layer 5b, the dissolved metal may be deposited, and the deposited metal may cause a short circuit between the word lines WL.

For this reason, when the opening 15 in the present modification is formed in the insulator 13 in the processes of FIGS. 5A to 5D, the insulator 13 in the vicinity of the connection portion C of each word line WL is also removed (FIG. 9C). As a result, the thickness of the insulator 11 on the second upper end E₂ of the air gap 12 is reduced, and the air gap 12 is opened.

Thereafter, the inter layer dielectric 16 is formed on the whole surface of the substrate 1 in the processes of FIGS. 6A to 6C. As a result, the inter layer dielectric 16 is formed on the air gap 12 in the vicinity of the connection portion C, and the air gap 12 is closed again (FIG. 9D). In this way, a new second upper end E₂′ of the air gap 12 is formed in the vicinity of the connection portion C. The upper face of the air gap 12 in the vicinity of the connection portion C may have a flat shape or a projecting shape.

In the present modification, when the contact plugs 21 to 25 are formed in the processes of FIGS. 7A to 7C, the metal line 17 is formed above the air gap 12 in the vicinity of the connection portion C (FIG. 9E). Reference character S denotes the lower face of this metal line 17.

According to the present modification, the upper end of the air gap 12 in the vicinity of the connection portion C can be lowered from the second upper end E₂ to the new second upper end E₂′. Therefore, according to the present modification, it is possible to increase the physical distance between the lower face S of the metal line 17 and the upper end of the air gap 12, enabling the avoidance of the contact between the metal line 17 and the air gap 12 more reliably. The lower face S of the metal line 17 in FIG. 9E is separated from the second upper end E₂′ of the air gap 12 by the inter layer dielectric 16.

The present modification makes it possible, by lowering the upper end of the air gap 12 in the vicinity of the connection portion C, to inhibit the chemical from intruding into the air gap 12 and inhibit a short circuit from being caused between the word lines WL, enabling the enhancement of the yield of the semiconductor devices.

In the present modification, the second upper end E₂′ of the air gap 12 is desirably lowered below the first upper end E₁. It is thereby possible to avoid the contact between the metal line 17 and the air gap 12 still more reliably.

As described above, the present embodiment forms the gate contact 24 in the opening 15 of the insulator 13, thereby forming the gate contact 24 to penetrate the mask layer 6, the insulator 11 and the inter layer dielectric 16 and not to penetrate the insulator 13. This is also applied to the gate contacts 22 and 23. Therefore, the present embodiment makes it possible to simultaneously form these gate contacts 22 to 24 with the bit line contacts 21 and the diffusion layer contacts 25.

In addition, the height of the second upper end E₂′ of the air gap 12 is set low in the present embodiment. For example, the second upper end E₂′ of the air gap 12 is set to be lower than the first upper end E₁. Therefore, the present embodiment makes it possible to inhibit the contact between the metal line 17 and the air gap 12.

### Second Embodiment

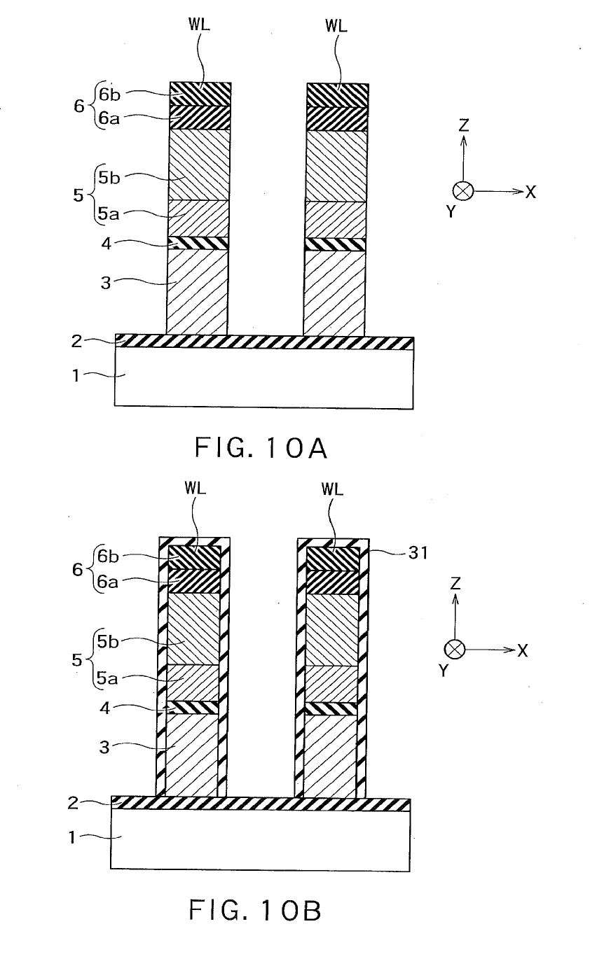

FIGS. 10A to 14B are cross sectional views showing a method of manufacturing a semiconductor device of a second embodiment. In the description of the present embodiment, explanation of matters common to the first embodiment will be omitted.

[FIG. 10A]

First, cell transistors (word lines WL) are formed on a substrate 1 (FIG. 10A). Each cell transistor includes the substrate 1, a gate insulator 2 as an example of a first insulator, a first conductive layer 3 as an example of a charge storage layer, an inter gate insulator 4 as an example of a second insulator, a second conductive layer 5 as an example of a gate conductor, and a mask layer 6. The second conductive layer 5 includes a semiconductor layer 5a and a metallic layer 5b. The mask layer 6 includes a first mask layer 6a and a second mask layer 6b.

The first conductive layer 3 functions as a floating gate. An example of the first conductive layer 3 is a polysilicon layer. The second conductive layer 5 functions as a control gate (word line WL). An example of the semiconductor layer 5a of the second conductive layer 5 is a polysilicon layer. An example of the metallic layer 5b of the second conductive layer 5 is a tungsten layer.

[FIG. 10B]

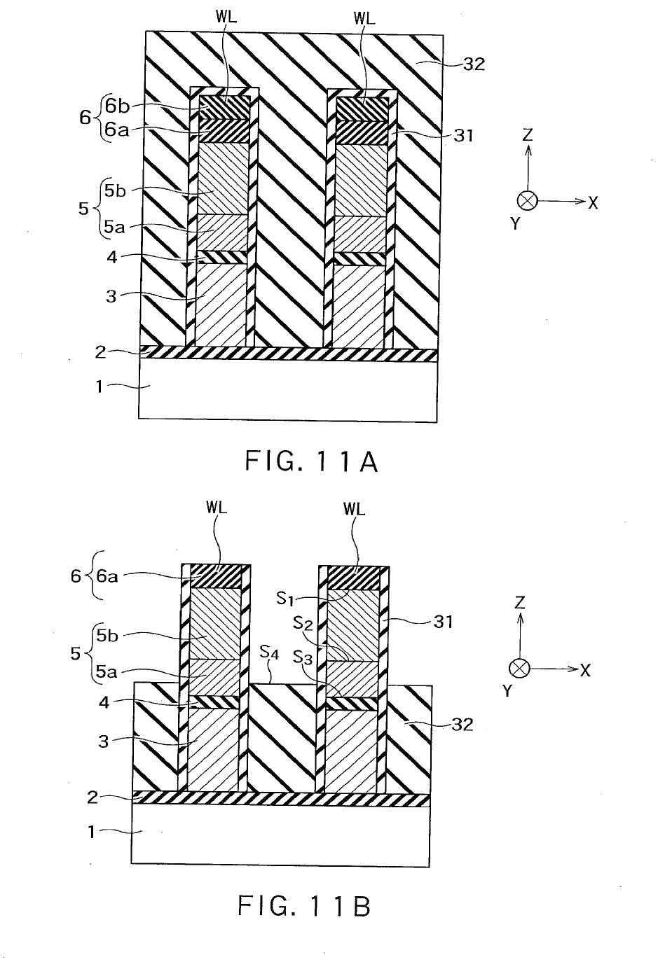

Next, a first sacrificial film 31 is formed on the whole surface of the substrate 1 (FIG. 10B). As a result, the first sacrificial film 31 is formed on the side faces of the first and second conductive layers 3 and 5 and the like. The first sacrificial film 31 is, for example, a silicon oxide film. The first sacrificial film 31 is an example of a first film.

[FIG. 11A]

Next, a second sacrificial film 32 is formed on the whole surface of the substrate 1 (FIG. 11A). As a result, the cell transistors are embedded in the second sacrificial film 32, and the second sacrificial film 32 is formed on the side faces of the first and second conductive layers 3 and 5 and the like through the first sacrificial film 31. The second sacrificial film 32 is, for example, an amorphous silicon film. The second sacrificial film 32 is an example of a second film.

[FIG. 11B]

Next, the second sacrificial film 32 is etched back by RIE (FIG. 11B). As a result, an upper face S₄ of the second sacrificial film 32 is lowered to a height between a lower face S₃ of the semiconductor layer 5a and a lower face S₂ of the metallic layer 5b. At this point, the second mask layer 6b is also removed. Reference character S₁ denotes an upper face of the metallic layer 5b.

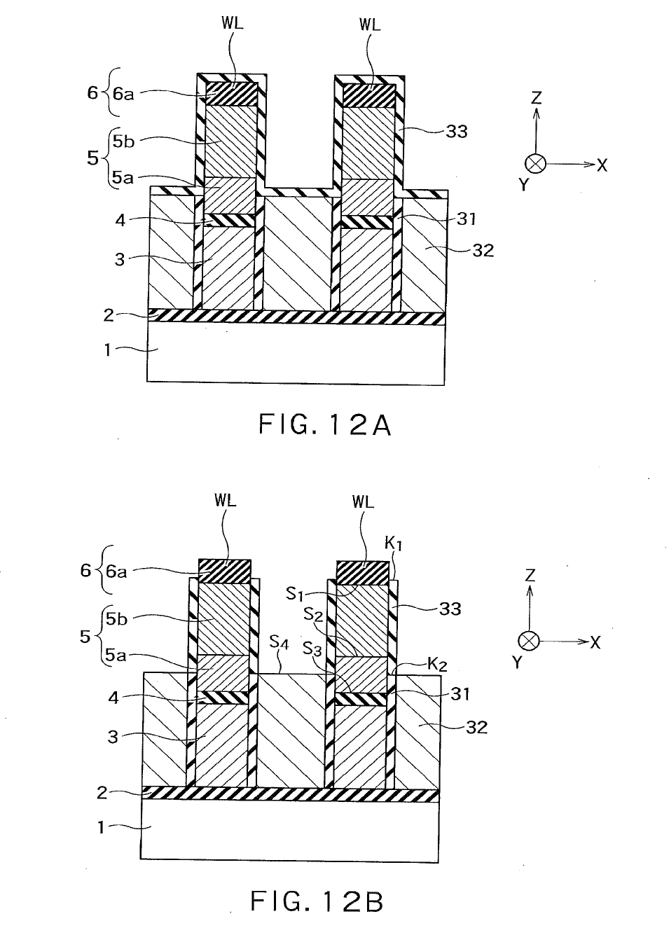

In this way, the second sacrificial film 32 is formed to cover the side faces of the first conductive layer 3 and portions of the side faces of the semiconductor layer 5a. The remaining portions of the side faces of the semiconductor layer 5a and the side faces of the metallic layer 5b are exposed from the second sacrificial film 32.

[FIG. 12A]

Next, the first sacrificial film 31 exposed from the second sacrificial film 32 is removed using a dilute hydrofluoric acid (FIG. 12A). As a result, the first sacrificial film 31 is removed from the side faces of the metallic layer 5b and the portions of the side faces of the semiconductor layer 5a.

Next, an insulator 33 is formed on the whole surface of the substrate 1 (FIG. 12A). As a result, the insulator 33 is formed on the side faces of the metallic layer 5b and the portions of the side faces of the semiconductor layer 5a. The insulator 33 is an example of a third insulator.

The insulator 33 in the present embodiment is desirably formed of an insulator material with which the insulator 33 is difficult to come off from the side faces of the metallic layer 5b even if the insulator 33 is thin. An example of such an insulator 33 is a silicon nitride film. In this case, the insulator 33 is formed by LPCVD, for example. The thickness of the insulator 33 is, for example, 1 nm to 3 nm (e.g., about 2 nm). The insulator 33 in the present embodiment is formed in order to prevent metallic atoms in the metallic layer 5b from diffusing.

[FIG. 12B]

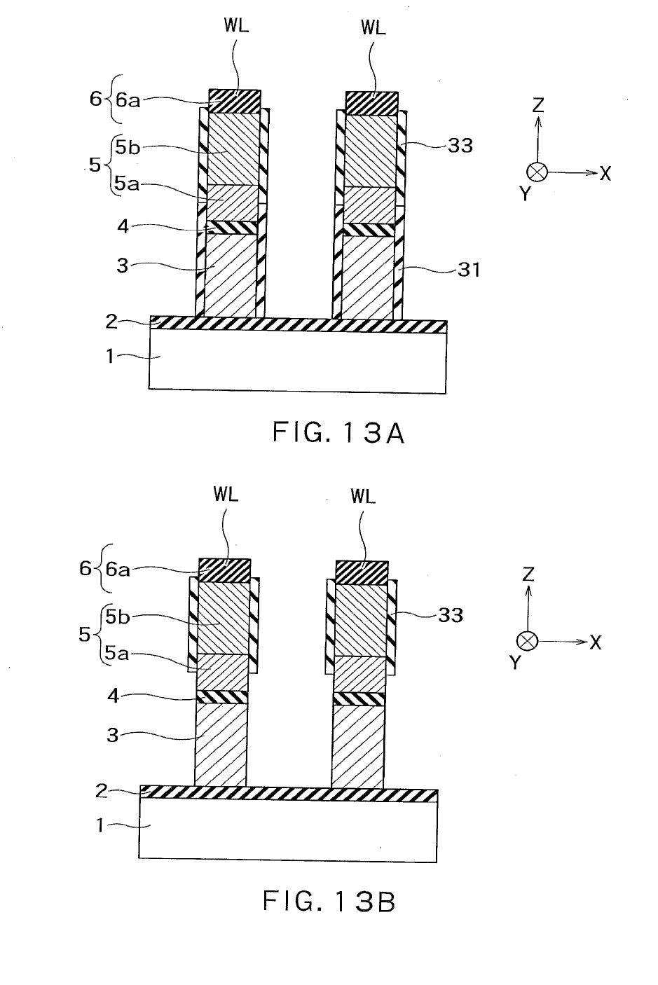

Next, the insulator 33 is etched by RIE to remove the insulator 33 from the upper faces of the first mask layer 6a and the second sacrificial film 32 (FIG. 12B). As a result, the insulator 33 is processed into a shape having an upper end K₁ that is higher than the upper face S₁ of the metallic layer 5b and a lower end K₂ that is lower than the lower face S₂ of the metallic layer 5b and higher than the lower face S₃ of the semiconductor layer 5a. In other words, the present embodiment can form the insulator 33 to locally cover the metallic layer 5b.

[FIGS. 13A and 13B]

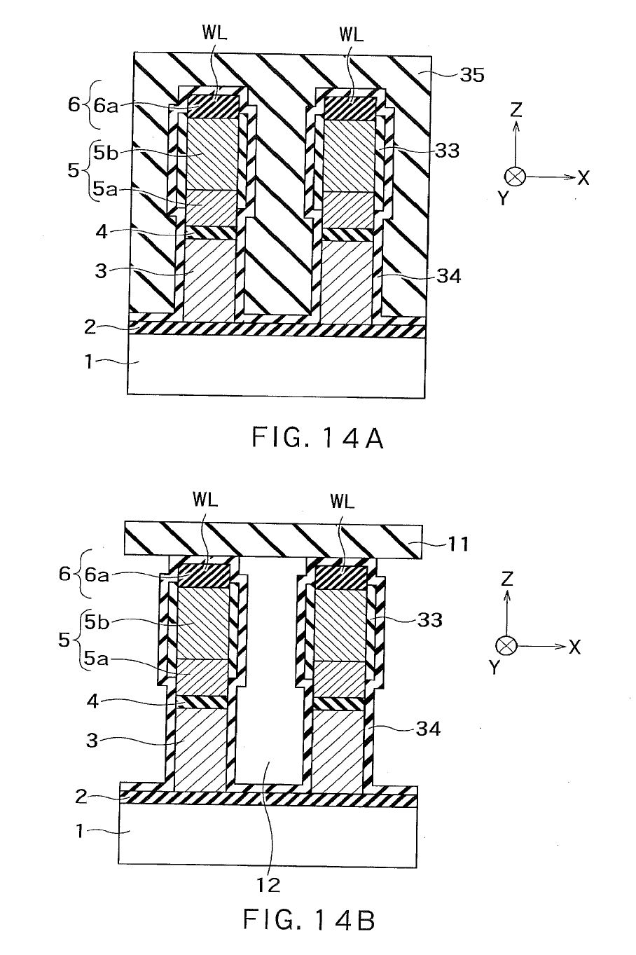

Next, the second sacrificial film 32 is removed using a choline-based chemical (FIG. 13A). Next, the first sacrificial film 31 is removed using a dilute hydrofluoric acid (FIG. 13B). As a result, the first and second sacrificial films 31 and 32 are removed from the side faces of the first conductive layer 3 and portions of the side faces of the semiconductor layer 5a.

[FIGS. 14A and 14B]

Next, an insulator 34 is formed on the whole surface of the substrate 1 (FIG. 14A). As a result, the insulator 34 is formed on the side faces of the cell transistors. The insulator 34 is formed to be in contact with the side faces of the first conductive layer 3 and the portions of the side faces of the semiconductor layer 5a. The insulator 34 is, for example, a silicon oxide film. The insulator 34 is an example of a fourth insulator.

Next, an inter layer dielectric 35 is formed on the whole surface of the substrate 1 (FIG. 14A). As a result, the cell transistors are covered with the inter layer dielectric 35. The inter layer dielectric 35 is, for example, a silicon oxide film. The inter layer dielectric 35 is also an example of the fourth insulator.

In the present embodiment, the processes of FIG. 2A to FIG. 7C in the first embodiment may be performed after the insulator 34 is formed (FIG. 14B). FIG. 14B shows the insulator 11 and the air gaps 12 that are formed by these processes.

As described above, after the word lines WL are processed, the metallic layer 5b in the present embodiment is not left to be exposed but is covered with the insulator 33. Therefore, the present embodiment makes it possible to inhibit the contamination due to the metallic layer 5b from having an adverse effect on the reliability of the cell transistors.

In addition, the insulator 33 in the present embodiment is formed of an insulator material with which the insulator 33 is difficult to come off from the side faces of the metallic layer 5b even if the insulator 33 is thin. Therefore, the present embodiment makes it possible to maintain the reliability of the cell transistors while preventing the insulator 33 from hindering the miniaturization of the semiconductor device.

In addition, the insulator 33 in the present embodiment is processed into the shape having the upper end K₁ that is higher than the upper face S₁ of the metallic layer 5b and the lower end K₂ that is lower than the lower face S₂ of the metallic layer 5b and higher than the lower face S₃ of the semiconductor layer 5a, and locally cover the metallic layer 5b. Therefore, the present embodiment makes it possible to reduce the regions where the cell transistors are covered with the insulator 33, thereby preventing the insulator 33 from hindering the miniaturization and fabrication of the semiconductor device. For example, the present embodiment makes it possible, by reducing the regions where the cell transistors are covered with the insulator 33, to increase the volume of the air gap 12.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
a gate conductor provided on the substrate;
a first insulator provided on the gate conductor;
a second insulator provided on the first insulator and including an opening;
a third insulator provided on the second insulator and provided in the opening; and
a first contact plug provided in the first and third insulators, positioned in the opening, and electrically connected to the gate conductor.

2. The device of claim 1, wherein
the first insulator includes a first layer and a second layer provided on the first layer,
the second insulator is formed of a same kind of insulator material as the first layer, and
the third insulator is formed of a same kind of insulator material as the second layer.

3. The device of claim 1, wherein the first contact plug is provided on a gate electrode or a pad electrode included in the gate conductor.

4. The device of claim 1, further comprising a second contact plug provided in the second and third insulators on the substrate and electrically connected to the substrate.

5. The device of claim 4, wherein the second contact plug is provided on a source or drain diffusion layer of a transistor on the substrate, or on a diffusion layer positioned between transistors on the substrate.

6. The device of claim 1, further comprising:
gate conductors provided on the substrate;
an air gap provided between the gate conductors under the first, second or third insulator; and
a metallic layer provided in the first, second or third insulator above the air gap.

7. The device of claim 6, wherein the metallic layer contains tungsten.

8. The device of claim 6, wherein
at least one of the gate conductors includes a first portion extending in a first direction and a second portion extending in a second direction that is different from the first direction, and
the metallic layer is provided above the air gap in a vicinity of a connection portion between the first portion and the second portion.

9. The device of claim 8, wherein a lower face of the metallic layer is separated, by the third insulator, from an upper end of the air gap in the vicinity of the connection portion between the first portion and the second portion.

10. The device of claim 8, wherein the air gap includes a first upper end and a second upper end that is lower than the first upper end and positioned in the vicinity of the connection portion between the first portion and the second portion.

11. A semiconductor device comprising:
a substrate;
a charge storage layer provided on the substrate through a first insulator;
a gate conductor provided on the charge storage layer through a second insulator, and including a semiconductor layer and a metallic layer on the semiconductor layer; and
a third insulator provided on a side face of the metallic layer, and including an upper end that is higher than an upper face of the metallic layer and a lower end that is lower than a lower face of the metallic layer and higher than a lower face of the semiconductor layer.

12. The device of claim 11, wherein the metallic layer contains tungsten.

13. The device of claim 11, wherein the third insulator contains nitrogen.

14. The device of claim 11, further comprising a fourth insulator provided to be in contact with side faces of the charge storage layer and the semiconductor layer.

15. A method of manufacturing a semiconductor device, comprising:
forming a charge storage layer on a substrate through a first insulator;
forming a gate conductor on the charge storage layer through a second insulator, the gate conductor including a semiconductor layer and a metallic layer on the semiconductor layer;
forming a first film on side faces of the charge storage layer, the semiconductor layer and the metallic layer;
removing the first film from the side face of the metallic layer;
forming, after the first film is removed from the side face of the metallic layer, a third insulator on the side face of the metallic layer; and
removing, after the third insulator is formed on the side face of the metallic layer, the first film from the side faces of the charge storage layer and the semiconductor layer.

16. The method of claim 15, further comprising forming, before the first film is removed from the side face of the metallic layer, a second film on the side faces of the charge storage layer and the semiconductor layer through the first film,
wherein the first film is removed from the side face of the metallic layer in a state where the second film is formed on the side faces of the charge storage layer and the semiconductor layer through the first film.

17. The method of claim 16, wherein the second film includes an upper face that is lower than a lower face of the metallic layer and higher than a lower face of the semiconductor layer.

18. The method of claim 15, wherein the metallic layer contains tungsten.

19. The method of claim 15, wherein the third insulator contains nitrogen.

20. The method of claim 15, further comprising forming, after the first film is removed from the side faces of the charge storage layer and the semiconductor layer, a fourth insulator that is in contact with the side faces of the semiconductor layer and the charge storage layer.
